(19) United States
(12) Patent Application Publication
(10) Pub. No.: US 2026/0047003 A1
(43) Pub. Date: Feb. 12, 2026

(54) High-Density Multi-Level Interconnects for Harsh Environments and Power Packaging and Method of Making The Same

(71) Applicant: Board of Trustees of the University of Arkansas, Little Rock, AR (US)

(72) Inventors: Zhong Chen, Fayetteville, AR (US); Tanner W. Rice, Fayetteville, AR (US); Pengyu Lai, Fayetteville, AR (US)

(21) Appl. No.: 19/297,549

(22) Filed: Aug. 12, 2025

Related U.S. Application Data
(60) Provisional application No. 63/682,015, filed on Aug. 12, 2024.

(51) Int. Cl. H05K 1/02; H01L 23/00; H01L 23/498; H01L 23/538; H01L 25/065; H05K 1/18; H05K 3/12; H05K 3/14

(52) U.S. Cl. CPC H05K 1/0298; H01L 23/49866; H01L 23/5383; H05K 1/181; H05K 3/1275; H05K 3/146; H01L 24/29; H01L 25/0655; H01L 2224/29144; H01L 2224/29164; H01L 2224/29169; H05K 2201/0317; H05K 2201/032; H05K 2201/0338; H05K 2201/0352; H05K 2203/068

(57) ABSTRACT

A high-density multi-level interconnect device for harsh environment applications combines thin-film and thick-film processing technologies to achieve superior performance in extreme conditions. The device comprises an alumina substrate with a thin-film metal layer deposited via electron beam evaporation, including a 20 nm titanium adhesion layer and a 400 nm gold layer, followed by a screen-printed thick-film gold layer. The layers are annealed at 850° C. for 10 minutes to promote strong adhesion. This hybrid approach provides improved die shear strength and enhanced thermal cycling resistance. The interconnects are suitable for wide bandgap semiconductor devices operating at temperatures up to 500° C. in harsh environments including elevated temperature, high pressure, and acidic conditions.

### CROSS-REFERENCE TO RELATED APPLICATIONS

This application claims the benefit of U.S. Provisional Application No. 63/682,015, entitled “High-Density Multi-Level Interconnects for Harsh Environments and Power Packaging and Method of Making the Same,” filed on Aug. 12, 2024. The complete disclosure of said provisional application is hereby incorporated by reference.

### STATEMENT REGARDING FEDERALLY SPONSORED RESEARCH OR DEVELOPMENT

This invention was made with Government support under agreement number 80NSSC 19M0173 awarded by NASA. The Government has certain rights in the invention.

### BACKGROUND OF THE INVENTION

Semiconductor devices and integrated circuits (ICs) designed for operation in harsh environments, such as elevated temperature and high pressure, are emerging due to the requirements of gas and oil exploration, nuclear energy, and aerospace systems. The high-temperature conditions potentially damage the normal operation and the longevity of the electronic devices. For example, the high-temperature, high-pressure environments experienced by Venus landing probes in the past greatly decreased the operation time of the electrical systems on those probes. such that they ceased operation within 110 minutes of touchdown. Therefore, devices and ICs fabricated with wide bandgap (WBG) materials (e.g., SiC and GaN) have been developed for applications with operating temperatures higher than 500° C. Although the devices have been characterized at elevated temperatures, the packaging methodologies and processes have not been fully explored yet, which significantly limits the operating temperature of electrical systems designed to operate in harsh environments.

Among the fabrication and packaging processes of semiconductor devices and ICs, metal interconnection is one of the most critical components as it significantly affects the RC delay. For decades, thick film methods with screen printing process have been implemented as primary mechanisms for metal interconnects in harsh environments and power packaging. Thick film patterns are able to use screen printing methods for application; however, the density of packaging and level of interconnects are limited by the screen-printing process (e.g., minimum line width and minimum distance between metal traces). For high-temperature applications, many different types of ceramic substrates have been considered, including beryllium oxide, aluminum nitride, and alumina. Out of all the previously mentioned candidates, alumina proves to not only provide a most similar coefficient of thermal expansion (CTE) but is also inexpensive relative to its counterparts. Although thick film interconnection has been developed for high-temperature applications, high-temperature thin film interconnection is still highly desirable to scale down the device and circuit sizes.

It would therefore be desirable to develop multi-level interconnects combining thin film process and thick film process for harsh environment conditions that offers high-density, low-cost, and high-thermal capabilities in terms of resistivity, die shear strength, and applications in harsh environments.

### BRIEF SUMMARY OF THE INVENTION

The present invention is directed to multi-level interconnects combining thin film process and thick film process for harsh environment conditions and methods for making the same. The goal of this invention is to show a high temperature resistant solution with a combination of both thin-film processing as well as thick-film processing that allows for not only the advantages of screen printing tooling, but also processes that include processing seen in modern semiconductor packaging.

Reliability in semiconductor devices and packing is always in high demand. As wide bandgap semiconductors that can survive higher temperatures and harsher environments become more readily available, technologies that include packaging must also keep up with it as well. This thin-and thick-film hybrid of packaging not only provides newer semiconductor technologies with multi-layer connectivity, high density, and high temperature capabilities, but also the ability to resist the acceleration and deceleration experienced in space flight based on data captured through the use of die shear testing.

These and other features, objects, and advantages of the present invention will become better understood from a consideration of the following detailed description of the preferred embodiments and appended claims in conjunction with the drawings as described following:

### BRIEF DESCRIPTION OF THE DRAWINGS

FIG. 1 is a box plot showing the die shear strength of the thick film sample before and after thermal baking and cycling.

FIG. 2 is a box plot showing the die shear strength of the thin film sample before and after thermal baking and cycling.

FIG. 3 is a box plot showing the die shear strength of the hybrid thin/thick film sample before and after thermal baking and cycling.

FIG. 4 is an image of a thick film sample with silicon dies attached and ready for testing.

FIG. 5 is the image of the process flow of the combined thin and thick film process.

### DETAILED DESCRIPTION OF THE INVENTION

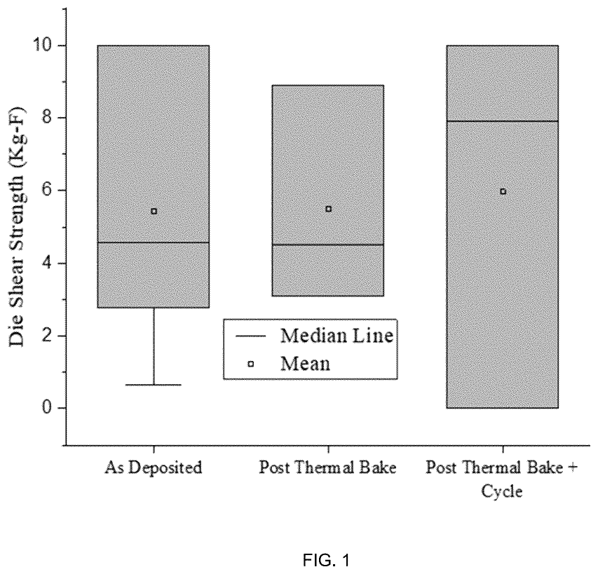

With reference to FIGS. 1-5, the preferred embodiments of the present invention may be described. The present invention is directed to high-density multi-level interconnects for harsh environments and power packaging and methods of making the interconnects.

High temperature, high pressure, acidic environments such as the surface of Venus have not been able to be explored for multiple hours as to date. Wide band gap (WBG) devices, such as silicon carbide devices and gallium nitride devices, have been both devices that are able to resist the harsh environments such as Venus, given the temperatures, pressure and composition of its atmosphere. Allowing for the performance of the die to resist not only the environment but also the violent entry with the sudden force changes caused by the engine of the probe or lander is of the most importance in terms of having a successful mission. Landers and probes go through launches of upward to four times the amount of gravity as seen as sea level. The contact to hold a device in place is imperative to allow for the device to operate nominally.

Thin-film metals use processes such as chemical vapor deposition or physical vapor deposition to deposit metals with a thickness as few as nanometers. Thick-film deposition uses a process of screen printing to deposit metallization in the thicknesses of more than one micrometer. Thin-film and thick-film samples have been explored in the development of the embodiments of the invention described herein, with the measurement of die shear testing. This allows for the samples to react and see if the adhesion material is strong. Both thin and thick film metals have been tested.

In an embodiment of the invention, a thin film is integrated with a thick film to enhance the die shear strength of the thin film while maintaining its micrometer-scale precision. A thin metal layer is first deposited onto the substrate via electron beam (E-beam) evaporation to improve the adhesion of the subsequent thick film layer. After the thin film deposition, the thick film is screen-printed on top of the thin layer. The sample is then annealed at 850° C. for 10 minutes to promote strong adhesion between the thin and thick films.

The embodiment as just described utilizes an alumina substrate. Alumina is chemically inert and exhibits excellent thermal and mechanical properties. Given that the process requires annealing at 850° C., alumina is an appropriate choice to ensure substrate stability and prevent thermal degradation. Gold and titanium are selected as the thin and thick film materials in certain embodiments due to their low electrical resistivity. Additionally, the coefficients of thermal expansion (CTE) of alumina are well-matched with those of gold and titanium, minimizing thermal stress.

Using testing of silicon chips, thin and thick film devices were tested against a combined thin-film and thick-film sample. After the thermal cycling and baking at 500° C., the hybrid sample improved in the die shear testing. The use of a combination of both thick-film and thin-film technology has proven durable in high-temperature testing and thermal cycling from room temperature to 450° C.

Current research form samples that use this combined thin film and thick film design has shown promising results. Thin and thick film samples show a good die shear strength test, however, after multiple thermal cycling and high temperature tests, the hybrid thin-film and thick-film thermal testing allowed for samples to pass the specification MIL STD 2019. This combination of thin-film and thick-film technology allows for a sample to be able to resist not only the vibration of a spacecraft but allows for samples to enjoy packaging that is able to account for the harsh environment due to gold's inertness. Packaging includes alumina alongside gold for the interconnect due to its low reactivity, allowing samples to be able to survive these extreme environments.

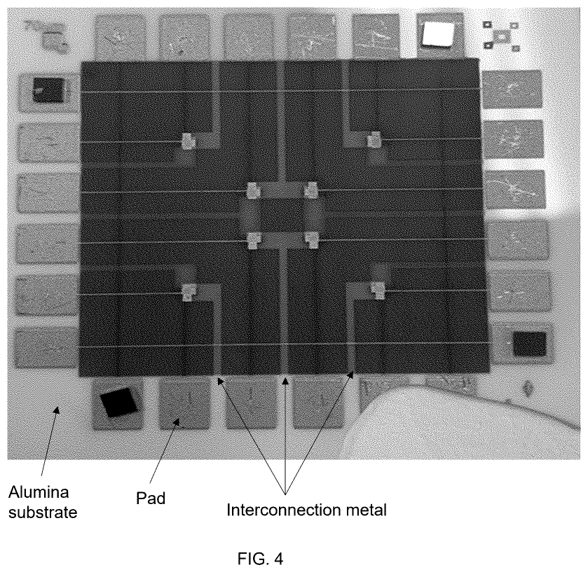

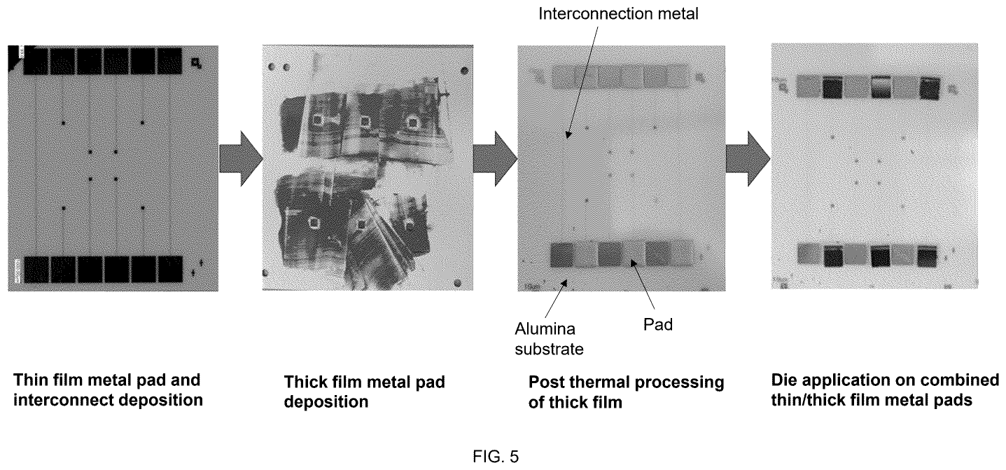

Current results show samples with an improved shear strength from thin-film and thick-film samples. Multiple pads were made with photolithography and screen printing for thin film and thick film, respectively. For thin film, a 20 nm Titanium (Ti) adhesion layer and 400 nm gold layer were deposited with e-beam, and a gold (Au) layer was screen printed and cured for thick film. Both thin and thick film designs were the same and can be seen in FIG. 4. Multiple silicon samples were applied to the pads using an AuPtPd paste. The hybrid sample used the previous thin-and thick-film methods, with a 20 nm Titanium (Ti) and 400 nm gold (Au) layer being deposited by e-beam, before an additional thick film gold (Au) layer was screen printed on the die pads. Like thin-and thick-film samples, multiple silicon samples were applied to the pads using AuPtPd paste. The samples were then baked using the manufacturer's specification. The process flow is outlined FIG. 5. After the silicon pads had adhered, use of a die shear was tested to see the force it took to destroy the sample with the maximum test limit being 10 kg. After testing, the devices were baked at 500° C. for 115 hours and the die shear test was then repeated. Finally, the samples were thermally cycled from 450° C. to room temperature 30 times and the devices were retested.

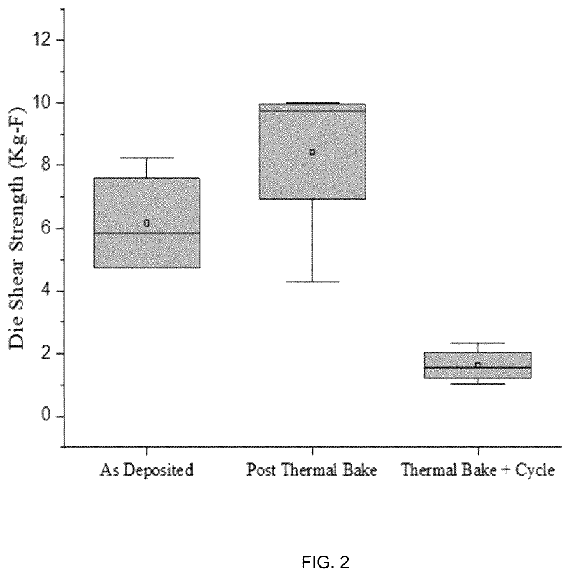

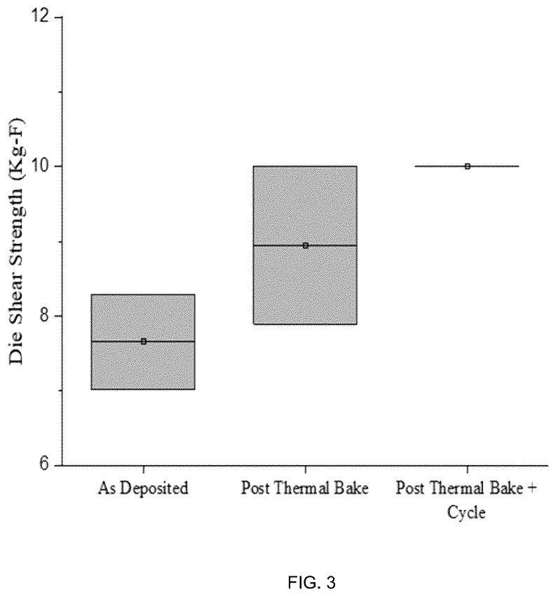

The results of the thin film can be seen in FIG. 1, which shows much variation in each test. Six samples were tested, and the range of their die shear strengths is plotted in the box with the mean values and median lines. The mean values of the die shear strength showed little change. Thick film results, which were extracted from six samples, can be seen in FIG. 2, where the die shear strengthen improved after the baking but significantly reduced after thermal cycling. The hybrid sample can be seen in FIG. 3. Three samples were tested. The deposited showed high shear strength, but also subsequent improvement with each thermal test. The increase in die shear strength would allow the device to resist failure from higher mechanical forces. Not only do the hybrid thin/thick film samples allow for better results after baking for a span of multiple days, but after thermal cycling, samples that used both thin and thick film processing allowed for a passing according to the MIL STD 2019 consistently throughout thermal testing when compared to only thin and only thick film samples.

Advantages of the invention in these embodiments include finer pitch and multilevel of interconnects with much improved density and higher resistance to hot environments. Conditions with potentially corrosive materials are used due to the chemical inertness of gold. Future development includes multiple layer of metallization to improve the density of the interconnects.

### REFERENCES

[1] Johnson, N. L., Handbook of soviet lunar and planetary exploration-volume 47 science and technology series, Amer. Astronau. Soc. Publ., 1979.Y. A. Surkov, V. L. Barsukov, L. P. Moskalayeva, V. P. Kharyukova, and A. L.
[2] Nasiri, Ardalan & Ang, Simon. (2020). High-Temperature Double-Layer Ceramic Packaging Substrates. Journal of Microelectronics and Electronic Packaging. 17. 99-105. 10.4071/imaps.1123535.
[3] Singh, R, and R K Ulrich. “High and Low Dielectric Constant Materials.” Pages 17-32, The Electrochemical Society, 1999, www.electrochem.org/dl/interface/sum/sum99/IF6-99-Pages26-30.pdf.
[4] R. Clark et al., “Thin Film Process Technologies for Continued Scaling,” 2018 IEEE 2nd Electron Devices Technology and Manufacturing Conference (EDTM), Kobe, Japan, 2018, pp. 100-101, doi: 10.1109/EDTM.2018.8421524.
[5] J. Larry, R. Rosenberg and R. Uhler, “Thick-film Technology: An Introduction to the Materials,” in IEEE Transactions on Components, Hybrids, and Manufacturing Technology, vol. 3, no. 2, pp. 211-225, June 1980, doi: 10.1109/TCHMT.1980.1135609.
[4] Chen, L. (2016, May 10). Electrical performance of a high temperature 32-I/O HTCC alumina package. NASA Technical Reports Server (NTRS). https://ntrs.nasa.gov/citations/20160014867
[5] M. Klein, B. Wall, R. Gruenwald, G. Bruckner and K. Ueki, “Design, assembly and reliability of a hermetic package for a 600° C. wireless temperature sensor,” 2015 IEEE 65th Electronic Components and Technology Conference (ECTC), San Diego, CA, USA, 2015, pp. 1351-1356, doi: 10.1109/ECTC.2015.7159773.
[6] R. R. Grzybowski, “Advances in electronic packaging technologies to temperatures as high as 500/spl deg/C,” 1998 High-Temperature Electronic Materials, Devices and Sensors Conference (Cat. No.98EX132), San Diego, CA, USA, 1998, pp. 207-215, doi: 10.1109/HTEMDS.1998.730699.

The present invention has been described with reference to certain preferred and alternative embodiments that are intended to be exemplary only and not limiting to the full scope of the present invention as set forth in the appended claims.

We claim:

1. A high-density multi-level interconnect device for harsh environment applications, comprising:
an alumina substrate;
a thin-film metal layer deposited on the substrate, the thin-film metal layer comprising a titanium adhesion layer and a gold layer; and
a thick-film metal layer screen-printed on top of the thin-film metal layer, the thick-film metal layer comprising gold;
wherein the thin-film and thick-film layers are annealed together to promote strong adhesion between the layers.

2. The device of claim 1, wherein the titanium adhesion layer has a thickness of approximately 20 nanometers.

3. The device of claim 1, wherein the gold layer of the thin film has a thickness of approximately 400 nanometers.

4. The device of claim 1, wherein the annealing is performed at 850° C. for 10 minutes.

5. The device of claim 1, wherein the device is configured to operate at temperatures up to 500° C.

6. The device of claim 1, wherein the alumina substrate provides a coefficient of thermal expansion that is well-matched with gold and titanium to minimize thermal stress.

7. The device of claim 1, wherein the device exhibits improved die shear strength after thermal cycling between room temperature and 450° C.

8. The device of claim 1, wherein the device passes MIL STD 2019 specifications after thermal testing.

9. The device of claim 1, further comprising silicon dies attached to the interconnect using an AuPtPd paste.

10. The device of claim 1, wherein the interconnect provides finer pitch and multilevel connectivity with improved density compared to thick-film only or thin-film only designs.

11. A method of manufacturing a high-density multi-level interconnect for harsh environment applications, comprising the steps of:
providing an alumina substrate;
depositing a thin-film metal layer on the substrate via electron beam evaporation, the thin-film metal layer comprising a titanium adhesion layer and a gold layer;
screen-printing a thick-film gold layer on top of the thin-film metal layer; and
annealing the substrate with the thin-and thick-film layers at 850° C. for 10 minutes to promote strong adhesion between the layers.

12. The method of claim 11, wherein the step of depositing the thin-film metal layer comprises depositing a titanium adhesion layer having a thickness of approximately 20 nanometers.

13. The method of claim 12, wherein the step of depositing the thin-film metal layer further comprises depositing a gold layer having a thickness of approximately 400 nanometers on the titanium adhesion layer.

14. The method of claim 11, wherein the screen-printing step deposits the thick film gold layer in a thickness greater than one micrometer.

15. The method of claim 11, further comprising a step of creating multiple pads using photolithography for the thin-film layer and screen printing for the thick-film layer.

16. The method of claim 11, further comprising a step of attaching silicon samples to the interconnect pads using AuPtPd paste after the annealing step.

17. The method of claim 16, further comprising a step of baking the attached silicon samples according to a manufacturer specification.

18. The method of claim 11, wherein the method produces an interconnect device that exhibits improved die shear strength after thermal baking at 500° C. for 115 hours.

19. The method of claim 11, wherein the method produces an interconnect device that maintains structural integrity after thermal cycling from 450° C. to room temperature for 30 cycles.

20. The method of claim 11, wherein the resulting interconnect device is suitable for applications in wide-bandgap semiconductor devices including silicon carbide and gallium nitride devices operating in harsh environments including elevated temperature, high-pressure, and acidic conditions.
